(19) United States
(12) Patent Application Publication
(10) Pub. No.: US 2024/0176084 A1
(43) Pub. Date: May 30, 2024

(54) PHOTONIC INTEGRATED CIRCUIT (PIC) FIRST PATCH ARCHITECTURE

(71) Applicant: Intel Corporation, Santa Clara, CA (US)

(72) Inventors: Jeremy D. Ecton, Gilbert, AZ (US); Srinivas V. Pietambaram, Chandler, AZ (US); Brandon Christian Marin, Gilbert, AZ (US); Gang Duan, Chandler, AZ (US); Bai Nie, Chandler, AZ (US)

(73) Assignee: Intel Corporation, Santa Clara, CA (US)

(21) Appl. No.: 18/059,923

(22) Filed: Nov. 29, 2022

(51) Int. Cl. G02B 6/42

(52) U.S. Cl. CPC G02B 6/428; G02B 6/136

(57) ABSTRACT

A PIC first patch architecture includes a solderless electrical connection at a die interconnect surface. Redistribution layers (RDLs) are patterned onto a face of an integrated circuit (IC) die and photonic integrated circuit (PIC) die prior to placement of the RDLs into a cavity in a glass layer. Optical interconnections for the PIC die are protected during RDL patterning and optical waveguides may be patterned into the glass layer fore or after assembling the PIC first patch including the RDL and glass layer.

### BACKGROUND

The off-package input/output (I/O) bandwidth demand of high-performance packages has been steadily increasing, putting pressure on packaging and I/O technologies to keep up with the demand. As a result, package pin counts and I/O data rates continue to increase. However, increased data rates reduce the electrical I/O reach (length of electrical printed circuit board (PCB) trace or cable). Accordingly, architectures and methods that improve I/O energy efficiency for high-performance packages are desirable.

### BRIEF DESCRIPTION OF THE DRAWINGS

FIG. 1 illustrates an example multi-die assembly that implements a PIC first patch architecture, in accordance with various embodiments.

FIGS. 2-8 are simplified cross-sectional illustrations depicting various stages of development of the PIC first patch architecture, in accordance with various embodiments.

FIG. 9 is a simplified cross-sectional illustration of a multi-die package that implements the PIC first patch architecture, attached to a printed circuit board (PCB), in accordance with various embodiments.

FIGS. 10-11 illustrate example process steps for a method for manufacturing and implementing the PIC first patch architecture, in accordance with various embodiments.

FIG. 12 is a top view of a wafer and dies that may be included in a microelectronic assembly, in accordance with any of the embodiments disclosed herein.

FIG. 13 s a simplified cross-sectional side view showing an implementation of an integrated circuit on a die that may be included in various embodiments, in accordance with any of the embodiments disclosed herein.

FIG. 14 is a cross-sectional side view of a microelectronic assembly that may include any of the embodiments disclosed herein.

FIG. 15 is a block diagram of an example electrical device that may include any of the embodiments disclosed herein.

### DETAILED DESCRIPTION

The off-package input/output (I/O) bandwidth demand and increased data rates of high-performance packages has been steadily increasing, putting pressure on packaging and I/O technologies to keep up with the demand. Additionally, I/O energy efficiency improvement with high-performance packages has drastically slowed. These technical problems have caused some concern that existing high performance packaging technologies are quickly approaching an I/O power wall.

A proposed solution to the technical problems of I/O efficiency and range of signaling includes implementing some optical transmission of signals, generally via waveguides in a glass substrate, with the electrical transmission of signals, and various architectures have been proposed to enable electrical and optical signal routing. Some proposed architectures require a solder attach to transmit electrical signals from die to substrate; however, the solder attach solution can add undesirable height to a package. To concurrently reduce the height introduced by the solder bumps and enable the placement of a photonic integrated circuit (PIC) flush on a glass surface containing surface waveguides, some solutions create a cavity in the glass and place the substrate within the cavity. However, creating the cavity with the necessary “step difference” to accommodate the solder bumps is a technical challenge.

Embodiments disclosed herein propose a technical solution to the above-described technical problems in the form of a die first architecture, more specifically referred to herein as a photonic integrated circuit (PIC) die first patch architecture. The PIC die first patch architecture is characterized by multiple die (e.g., ICs and PICs) bonded to a window frame glass interposer and wherein electrical connections for the ICs and PICs are patterned directly onto the ICs and PICs before placement into the window frame glass interposer, hence the label “die first.” These concepts are developed in more detail below.

Example embodiments are hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

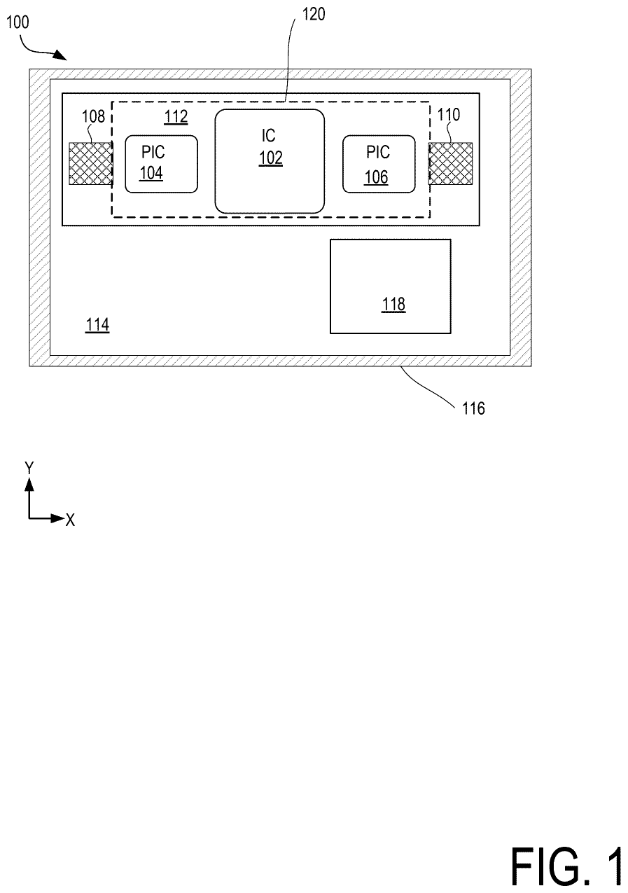

FIG. 1 provides an example multi-die assembly 100 that implements the PIC first patch architecture. The multi-die assembly 100 comprises an integrated circuit (IC) die 102 a first photonic integrated circuit (PIC) die 104 and a second PIC die 106. Optional fiber array units (FAUs) may be added. The PIC die 104 is operably connected to fiber array unit (FAU) 108 and the PIC die 106 is operably connected to FAU 110. As may be appreciated, this arrangement of die is just one example embodiment, in other multi-die assemblies, there may be more or less PIC die, more or less FAU components, more or less ICs, and the die may be arranged in any pattern (e.g., square (e.g., 2×2, 4×4, 6×6), rectangular (e.g., 2×4, 3×5, 4×7)). The die may be attached to a substrate 112. In various embodiments, the substrate 112 may comprise a printed circuit board, thin-film substrate, or another suitable substrate. In other embodiments, the substrate 112 may further be attached to a printed circuit board (PCB) 114; and in further embodiments, the multi-die assembly may include additional IC die, represented generally as die 118.

In various embodiments, the die in the multi-die assembly 100 can be overmolded with an encapsulant 116. The encapsulant 116 can comprise a molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a multi-die assembly 100. As part of a thermal management solution, a thermal conduction layer interface material (TIM) may be located over the die 102. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

The die 102, 104, 106, and 118, may be unpackaged integrated circuit die, and may alternatively be referred to as chips, chiplets, chip complexes, or chiplet complexes. The PICs employ at least some optical communication, and the fiber array units (FAUs) implement optical switching functionality. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components)). Any integrated circuit die, chip, or chiplet can implement any portion of the functionality of any processor unit described or referenced herein. Furthermore, a multi-die assembly 100 can have any shape, such as a substantially square shape, substantially rectangular shape or substantially circular shape.

The dashed line 120 narrows the focus to an area of the substrate 112 that may implement a PIC first patch architecture, as described herein.

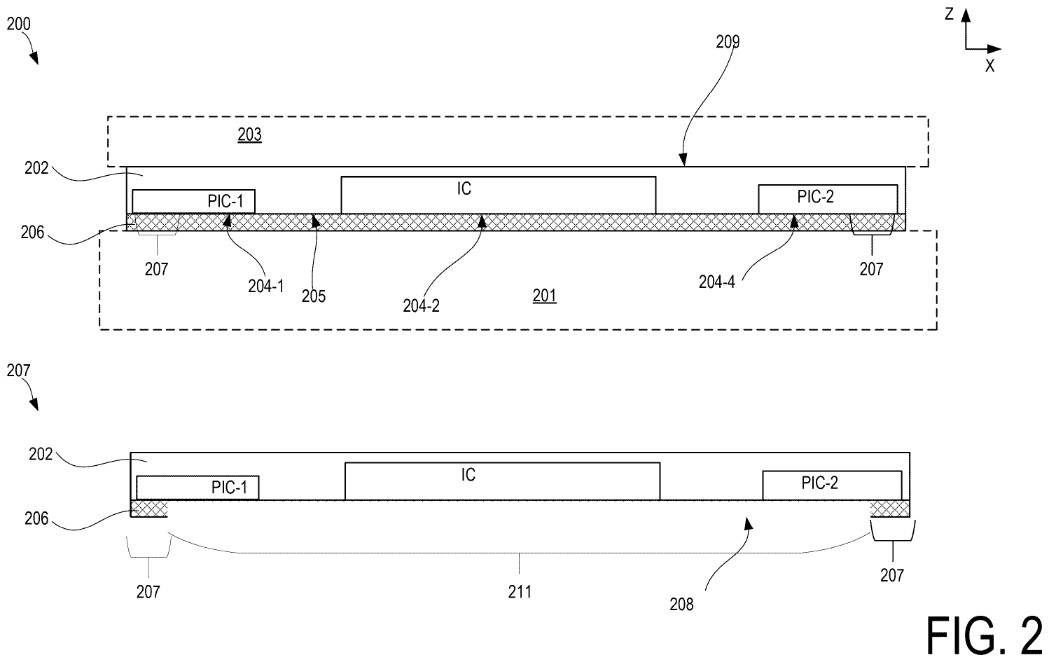

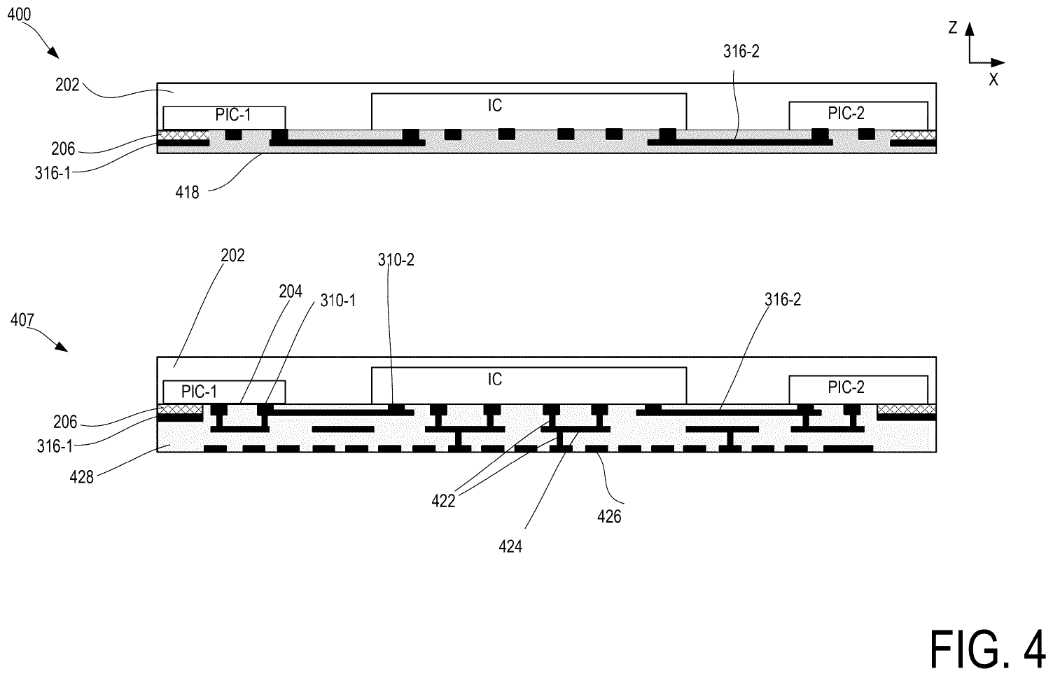

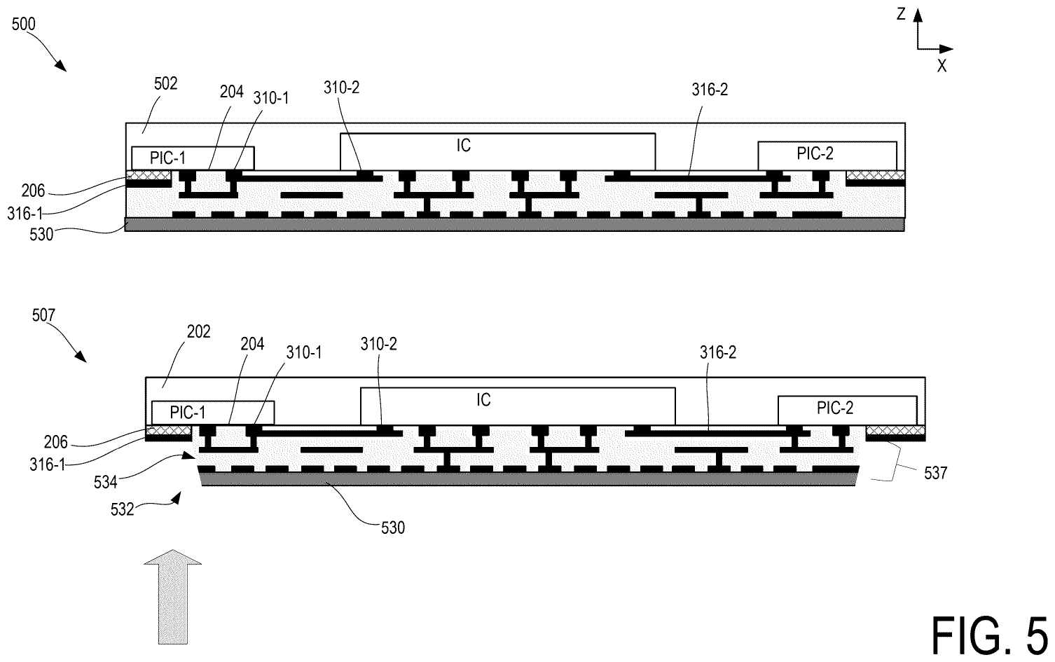

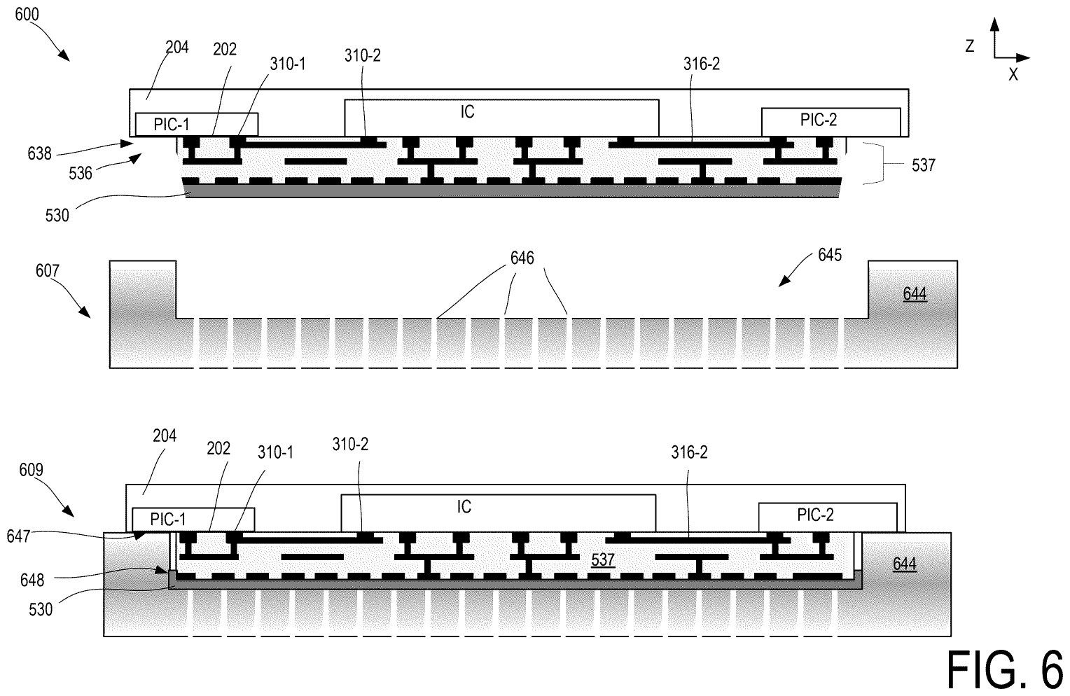

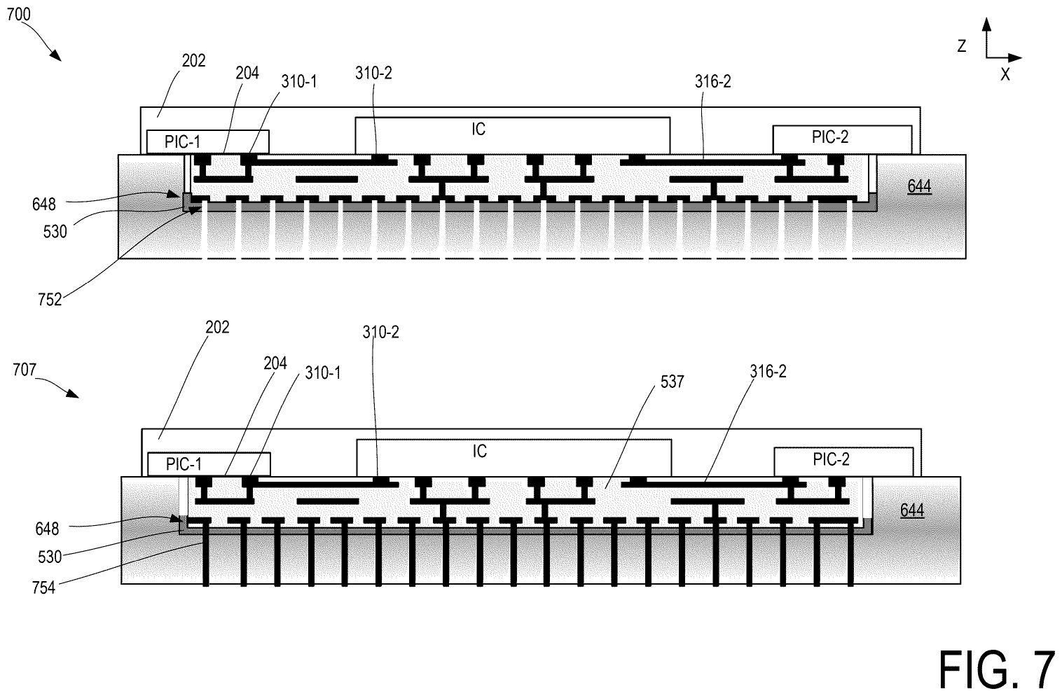

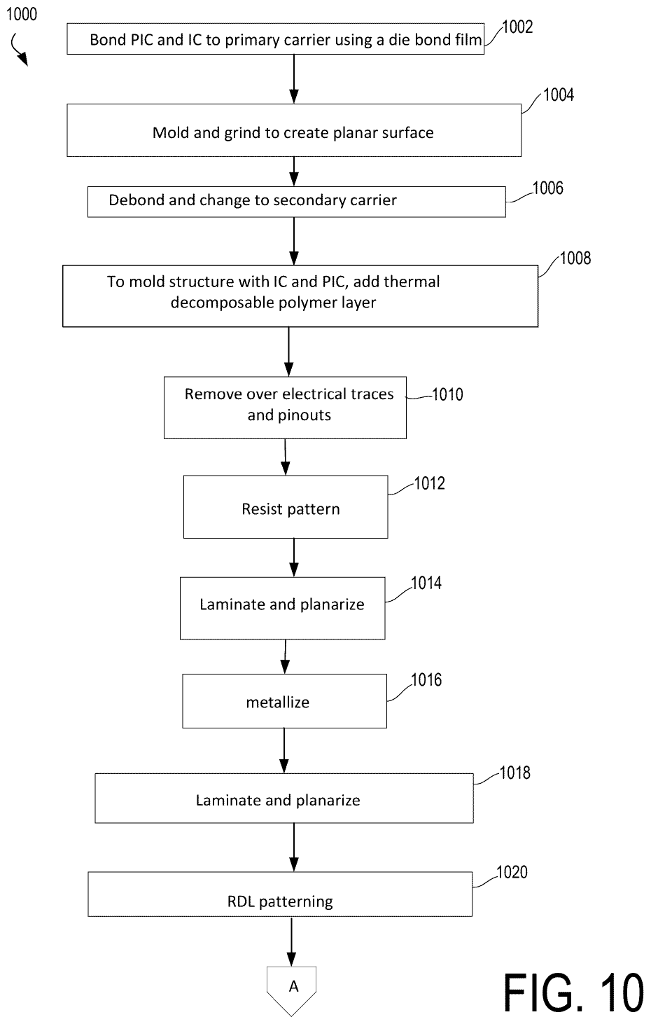

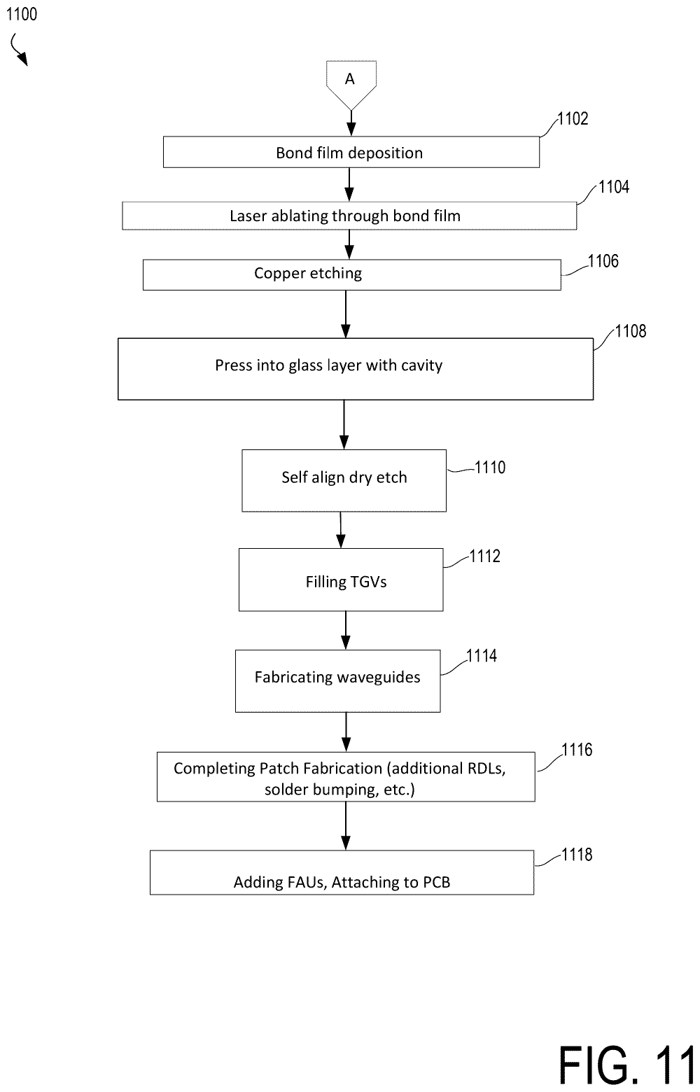

FIGS. 2-9 provide various embodiments and stages of development of the PIC first patch architecture. FIGS. 10 and 11 provide a process flow (1000 continuing to 1100) for creating embodiments described herein. The PIC first patch architecture is characterized by a mold 202 structure comprising a face 205 having a first portion 211 with electrical contacts for an integrated circuit (IC) die and electrical contacts for one or more photonic integrated circuit (PIC) die, and a second portion 207 comprising optical interconnects, generally for the one or more PIC die. The mold 202 structure may comprise a molding compound, dielectric materials, metal, ceramic, plastic, or a combination thereof, sufficient to secure the position of the IC die and two or more PIC die, as shown.

With reference to FIG. 2, the non-limiting embodiment 200 depicts the mold 202 structure with an IC die and two PIC die. The die are arranged face down in the mold structure 202, meaning that the die contacts and interconnects are at a lower surface (face 205) in the figures (indicated by 204-1 for PIC-1, 204-2 for the IC, and 204-4 for the PIC-2). The face 205 of the mold 202 structure is substantially planar.

To fabricate the embodiment shown, the die may be first placed on a primary carrier 201 (at 1002), e.g., using a die bond film (DBF), subjected to an overmold and grind process (at 1004) to add the mold structure 202 and to create a planar upper surface 209 on the mold 202 structure, and then the mold structure 202 can be de-bonded and transferred to a secondary carrier 203 (at 1006) that is bonded to the upper surface 209. Such an approach enables creating a die first patch that comprises die of variable thickness, keeping the electrical contacts all on a planar face of the mold structure. The DBF may comprise a low filler buildup film (e.g., with a filler percentage that is less than 30%), a liquid buildup film, polydimethylsiloxane (PDMS) or the like. The primary carrier 201 and secondary carrier 203 may be glass or any other suitable material to provide appropriate stiffness and planarity for the PIC first patch process. To simplify the images in the following figures, the secondary carrier 203 may be present but omitted.

During fabrication, a thermal decomposable polymer deposition layer 206 or other similar type of resist layer can be overlaid on the pinouts of the arrangement (at 1008), as shown. The thermal decomposable polymer deposition layer 206 can be employed to protect vulnerable optical connectors in the PIC and may be selected for the temperature at which it breaks down. Examples of material used for the thermal decomposition layer 206 include polynorborene (240-400 degrees Celsius) polyalkylcarbonates (200-300 degrees Celsius), and polyaldehydes (120-200 degrees Celsius). In some embodiments, acrylates and quinones can be added to sacrificial polymer blends to make them photodefinable. It should be noted that the alkaline robustness of these polymers makes them useful for various other photo-definable processes, such as backend bump plating. A pattern 208 is etched into the thermal decomposable polymer deposition layer 206 to reveal areas that have electrical traces and electrical pinouts (at 1010). The thermal decomposable polymer deposition layer 206 is left in place adjacent to the optical connectors, as indicated adjacent to the PIC-1 and PIC-2 (the one or more areas labeled second portion 207).

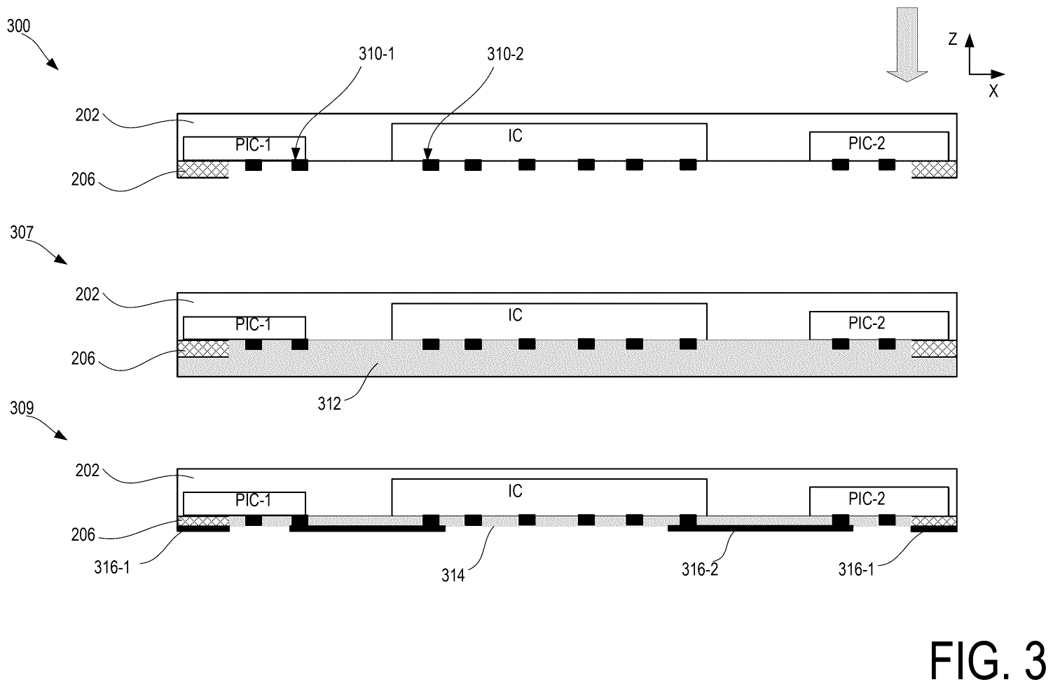

In embodiment 300, a resist pattern is added over the electrical pinouts of the die (at 1012) and the process begins building from north to south, with respect to the illustrations, or from positive Z to negative Z, as indicated with the arrow in the upper left of FIG. 3. The resist pattern includes traces and contacts at a pitch and arrangement for each PIC, as indicated with 310-1, and traces and contacts at a pitch and arrangement for the IC, as indicated with 310-2. As used herein, “pitch” means the physical distance at which a feature is repeated (e.g., the space from the center of one instance of a feature to the center of an adjacent instance of the feature). As used herein “fine pitch” generally means a die-scale pitch. Fine pitch dimensions may include a range of about 0.001 mm to about 0.3 mm. In some embodiments, features having a fine pitch have dimensions of about 1 μm (micron) or less. In other embodiments, features having a fine pitch may have dimensions of about 0.5 μm or less. In addition to the conductive contacts that are used to attach integrated circuit dies to a substrate patch, other features that can have a fine pitch include the vias in one or more RDLs adjacent to the pinouts for integrated circuit dies.

In contrast, “coarse pitch” generally means a package-level pitch, which is larger than a fine pitch. The coarse pitch geometries may be for a ball grid array (BGA) or a land grid array (LGA). In various embodiments, a BGA pitch is in a range of about 0.1 mm to about 1 mm, and LGA pitch is in a range of about 0.1 mm to about 1 mm.

Embodiment 307 illustrates a dielectric layer 312 laminated over the resist pattern (at 1014). The dielectric layer is then planarized to provide planar surface 314 and then a first die interconnect layer (conductive routing material, sometimes referred to as FLI or first level interconnect, or metallization step (at 1016)) is added adjacent to the dielectric layer 312 (i.e., a metallization is performed), as indicated in embodiment 309. The conductive routing material comprises copper or any other suitable metal providing electrical conductivity and meeting line and space requirements. The conductive routing material includes traces 316-2 for electrical communication between the IC and the PICs, as well metal etch stops 316-1, which are a layer of metal utilized to protect the vulnerable optical connectors.

The conductive routing material may be one layer of a plurality of redistribution layers (RDLs). In various embodiments, the RDLs can include, overlaid on the conductive routing material, a dielectric material, such as, a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, an RDL layer comprises a photo-imageable dielectric (PID).

In some embodiments, it is advantageous for the dielectric layer of the RDLs to have a CTE that matches that of integrated circuit dies (e.g., match the CTE of silicon) attached to the substrate patch. In some embodiments, the dielectric material of the RDL layers can have a CTE that is close (e.g., within 10%) to that of silicon. In other embodiments, the dielectric material of RDLs can be any type of epoxy molding compound.

Another dielectric lamination layer 418 may be added and planarized (at 1018) as illustrated with embodiment 400. Embodiment 407 illustrates further redistribution layer (RDL) patterning (at 1020), again being “built up” from north to south. In the non-limiting example of embodiment 407, the RDL patterning 428 generally includes vias 422, trace layer 424, and RDL trace layer 426. RDL trace layer 426 may be patterned at a fine pitch. As may be appreciated by those with skill in the art, since the vias 422 are created with the upside-down patterning, any taper in the via 422 geometry would include a widening of the via diameter as one moves toward the bottom of the page (traveling in the negative Z direction). Said differently, the vias 422 have walls that taper outward traveling axially away from the first portion or surface having the electrical contacts.

At the completion of the RDL patterning 428, a bond film 530 may be deposited (at 1102), as shown in embodiment 500. The bond film 530 may comprise a low filler buildup film (e.g., with a filler percentage that is less than 30%), a liquid buildup film, polydimethylsiloxane (PDMS) or the like. The bond film 530 may also be a hybrid or multilayered film consisting of conventional bond film material and the previously mentioned materials. In other embodiments, the bond film 530 may be Ajinomoto Build-Up film (ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df))

Embodiment 507 indicates performing a laser ablation on the structure, through the bond film (at 1104). The laser ablation is performed from the south to the north in the figure, or from negative Z toward positive Z axis, as indicated by the arrow next to the embodiment 507. The laser ablation opens a volume 532 located near the PIC-1 and PIC-2. As with the vias described above, sidewalls from the laser ablation step may have a taper indicated by arrow 543. The taper reflects that laser ablation creates a wider diameter at the surface it is applied to (i.e., the bond film layer) than the diameter at the depth to which it reaches (the metal etch stops). The laser ablation is stopped by the metal etch stops 316-1. The substrate layer 537 comprises the RDL layers sufficient to provide local electrical communication between the IC and the one or more PICs on a multi-die substrate patch. In some embodiments, the substrate layer 537 may be referred to as a bridge.

In embodiment 600, a copper etch is performed (at 1106) to remove the metal etch stops 316-1, and then heat is applied to remove the thermal decomposition layer. Together, this processing reveals (638) the optical connectors associated with the PICs. Embodiment 600 may be a standalone product, or it may be further processed as described herein.

Embodiment 607 indicates a substrate comprising a glass layer with a cavity 645 and one or more through-holes or through glass vias (TGVs). The TGVs are substantially perpendicular to a bottom surface of the glass layer, which is also substantially parallel to a bottom surface of the cavity. The respective TGVs have a diameter of about 2 to about 150 microns.

The glass layer 644 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂, Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. Glass layer 324 may comprise multiple glass sheets bonded together with an adhesion layer. In various embodiments, the glass layer 644 may have thickness in a range of about 20 microns to about 1 millimeter, +/−10%. The TGVs may be arranged at a fine pitch.

Embodiment 609 illustrates the structure of embodiment 600 pressed into the cavity 645 of the glass layer 644 (at 1108). Pressing the structure into the cavity brings the face or optical interconnects (second portion 207) of the one or more PICs flush with the upper surface of the glass layer at a periphery of the cavity (see arrow 647, PIC face flush, near cavity periphery), while causing the substrate layer 537 with the one or more patterned RDLs to be located in the cavity (in the Z direction in the figures, as shown), and also causes the bond film 530 to rise up (in the Z direction) around the edges of the structure, as indicated by the arrow to height 648. This upturn in the bond film 530 may have a height 648 in a range of about 1 micron to about 20 microns in thickness above the thickness of the bond film under the substrate layer 537, and the height may or may not be uniform, circumferentially. This upturn in the bond film 530 is a characteristic of this PIC first patch architecture.

As illustrated in embodiment 700, a self-align dry-etch may be performed (at 1110, again from south to north) to clear the bond film 530 where the TGVs are located, as indicated with arrow 752. The TGVs may then be filled with copper or another conductive material, establishing respective electrically conductive pathways with filled TGVs 754 from one or more conductive traces in the RDLs (substrate layer 537) through the glass layer 644. Embodiment 707 may be a standalone product or may be further processed.

In embodiment 800, waveguides may be fabricated (at 1114) in the glass layer 644 to complete optical communication paths to and from the PICs in the structure. Waveguides can include surface waveguides 858-1 and internal waveguides 858-2. Waveguides can complete optical communication between one or more PIC die on the die first patch (e.g., waveguides 858-2). Additionally, waveguides (e.g., waveguides 858-1) can extend from a PIC at one end to a terminus 859. The terminus 859 can be open or utilized for optical communication with another component, such as a fiber array unit (FAU).

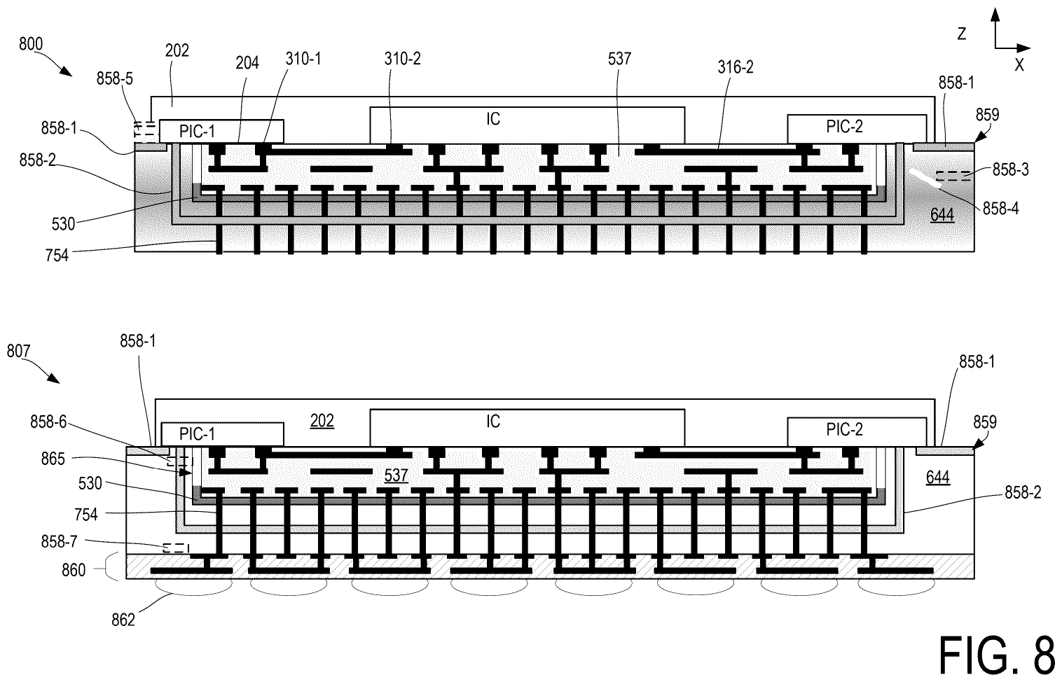

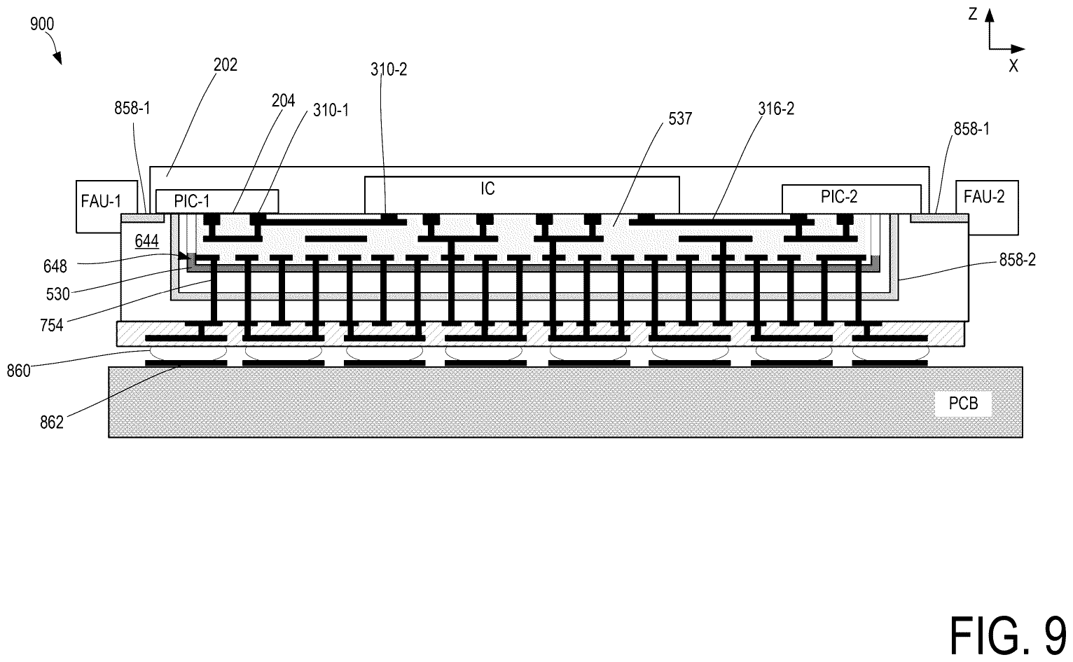

Embodiment 807 illustrates (at 1116) adding one or more backside RDLs 860 to the lower surface of the glass layer and adding solder bumps 862 to the one or more RDLs added to the lower surface of the glass layer of the structure. In various embodiments, air gap 865 may be present between the substrate layer 537 and wall of the cavity, above the bond film 530. The air gap may be between the bond film 530 and a PIC when it is attached (see, e.g., air gap 865 in between bond film 530 and PIC-1 in FIG. 8). The solder bumps 862 may be arranged at a coarse pitch. FIG. 9, embodiment 900 illustrates the embodiment 807 attached to a PCB (e.g., PCB 114) and the FAUs 108 and 110 may be attached to embodiment 807.

When an FAU is attached, the FAU 108 or 110 is attached to the glass layer 644 to be in optical communication with a respective PIC, e.g., via a terminus 859 of a waveguide 858-1.

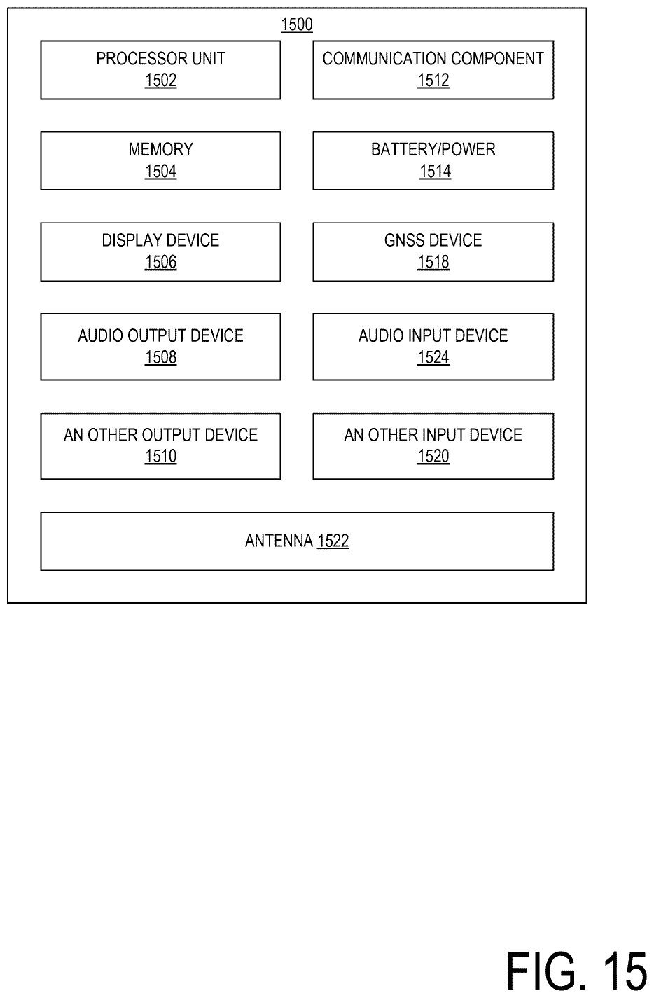

At the completion of 1118, the end product may a complete multi-die assembly or may be placed inside another product or device (e.g., device 1500 FIG. 15).

Several non-limiting alternatives to the above embodiments are also contemplated. On embodiment incorporates a bond film on a surface of the cavity. Another embodiment creates the waveguides first (instead of waveguide last, as described above). An issue with WG last evanescent coupling is that the coupling loss can be very sensitive to the gap between glass WG and PIC WG. In order to achieve evanescent coupling, the WG needs be created (“written”) very close to surface of the glass layer, if not exactly at the surface. However, it is technologically challenging to write the WG on a glass surface with a laser process, the process can create a surface ablation instead of forming the desired WG; this can be true whether the WG is written from the top side/surface or bottom side/surface. In some scenarios, this can either damage the PIC output or some ablation debris can contaminate the interface. Two optional embodiments are contemplated here. A first is to use edge coupling, which is copacetic with WG last approach. Edge coupling is indicated in FIG. 8, showing the WG 858-5 from PIC-1 extending leftward (858-1 would be removed), with the dielectric 644 extending up over WG 858-5, as indicated in dashed lines. Alternately, an embodiment could employ vertical coupling, using a mirror 858-4. In this example embodiment, WG 858-2 is removed, and WG 858-3 employs mirror 858-4. The mirror 858-4 can be a curved mirror or a collimation lens; either of these two options can help increase the alignment tolerance and improve a WG last approach. Moreover, a WG first approach can be employed, placing WG 858-7 as shown in embodiment 807. The WG first approach can improve die bonding accuracy, but it can be difficult to achieve optical coupling through the glass core. Adding a lens 858-6 or index matching film can increase alignment tolerance. Furthermore, additional layers may be inserted between PIC and glass. For example, an index matching bonding film can be applied or an antireflective coating.

Thus, various non-limiting embodiments of a PIC first patch architecture have been described. The disclosed embodiments enable a tighter electrical interconnect pitch (due to the die first approach that employs direct patterning onto interconnects) and concurrently relaxes relative bump thickness (rBTV) requirements. The embodiments have a solderless electrical connection at a first level interconnect (FLI). By enabling a “waveguide last” architecture embodiments can foster better alignment at the optical interconnects. And the PIC first patch architecture enables RDL within a glass cavity without requirement of performing the patterning directly inside of the cavity.

Unique features of this invention include (1) a solderless FLI with direct copper connection to RDL (die first), (2) bond film at bottom of glass cavity with a self-align dry etch, (3) bond film that potentially extends above at least some of the RDL along perimeter of cavity including an air gap 865 between the RDL (substrate layer 537) and glass cavity wall and/or (4) the surface of the glass layer and the PIC interface may also include a coupler (anti-reflective coating, index matching gel, etc.).

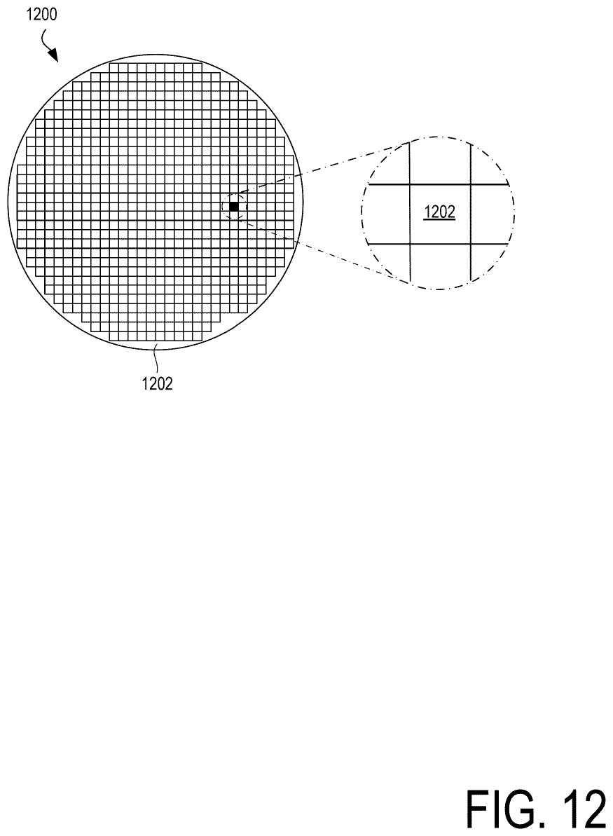

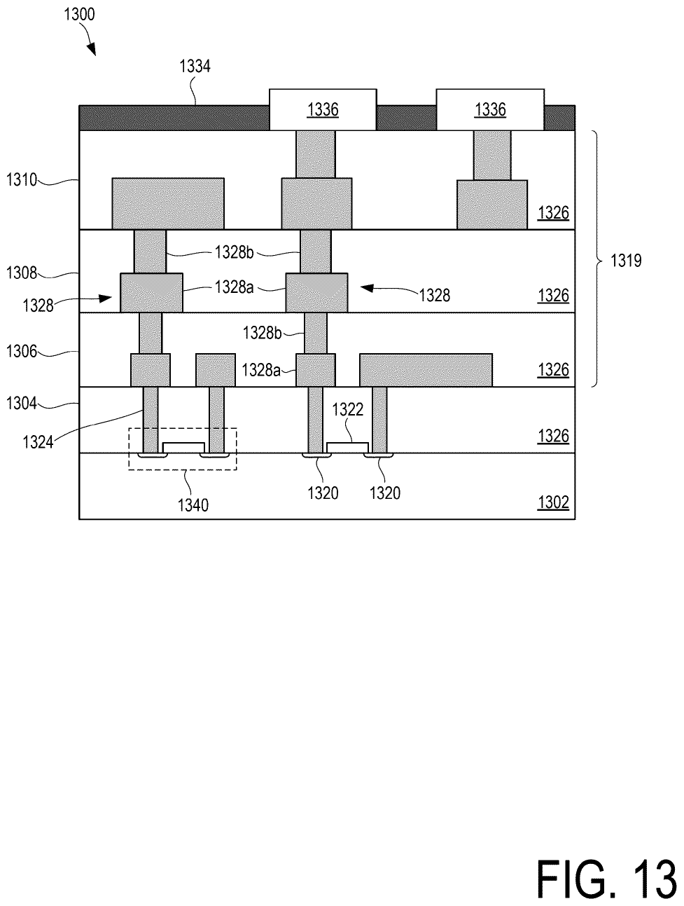

FIG. 12 is a top view of a wafer 1200 and dies 1202 that may be included in any of the embodiments disclosed herein. The wafer 1200 may be composed of semiconductor material and may include one or more dies 1202 formed on a surface of the wafer 1200. After the fabrication of the integrated circuit components on the wafer 1200 is complete, the wafer 1200 may undergo a singulation process in which the dies 1202 are separated from one another to provide discrete “chips” or destined for a packaged integrated circuit component. The individual dies 1202, comprising an integrated circuit component, may include one or more transistors (e.g., some of the transistors 1340 of FIG. 13, discussed below), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1202. For example, a memory array formed by multiple memory devices may be formed on a same die 1202 as a processor unit (e.g., the processor unit 1502 of FIG. 15) or other logic that is configured to store information in the memory devices or execute instructions stored in the memory array. In some embodiments, a die 1202 may be attached to a wafer 1200 that includes other die, and the wafer 1200 is subsequently singulated, this manufacturing procedure is referred to as a die-to-wafer assembly technique.

FIG. 13 is a cross-sectional side view of an integrated circuit 1300 that may be included in any of the embodiments disclosed herein. One or more of the integrated circuits 1300 may be included in one or more dies 1202 (FIG. 12). The integrated circuit 1300 may be formed on a die substrate 1302 (e.g., the wafer 1200 of FIG. 12) and may be included in a die (e.g., the die 1202 of FIG. 12).

The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit 1300 may be used. The die substrate 1302 may be part of a singulated die (e.g., the dies 1202 of FIG. 12) or a wafer (e.g., the wafer 1200 of FIG. 12).

The integrated circuit 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320.

The gate 1322 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may comprise a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be conducted to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuits having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page and/or in a direction across the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit 1300 (i.e., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit 1300 with another component (e.g., a printed circuit board). The integrated circuit 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit 1300 is a double-sided die, the integrated circuit 1300 may include another metallization stack (not shown) on the opposite side of the device layer(s) 1304. This metallization stack may include multiple interconnect layers as discussed above with reference to the interconnect layers 1306-1310, to provide electrically conductive paths (e.g., including conductive lines and vias) between the device layer(s) 1304 and additional conductive contacts (not shown) on the opposite side of the integrated circuit 1300 from the conductive contacts 1336.

In other embodiments in which the integrated circuit 1300 is a double-sided die, the integrated circuit 1300 may include one or more through-silicon vias (TSVs) through the die substrate 1302; these TSVs may make contact with the device layer(s) 1304, and may provide electrically conductive paths between the device layer(s) 1304 and additional conductive contacts (not shown) on the opposite side of the integrated circuit 1300 from the conductive contacts 1336. In some embodiments, TSVs extending through the substrate can be used for routing power and ground signals from conductive contacts on the opposite side of the integrated circuit 1300 from the conductive contacts 1336 to the transistors 1340 and any other components integrated into the die 1300, and the metallization stack 1319 can be used to route I/O signals from the conductive contacts 1336 to transistors 1340 and any other components integrated into the die 1300.

Multiple integrated circuits 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

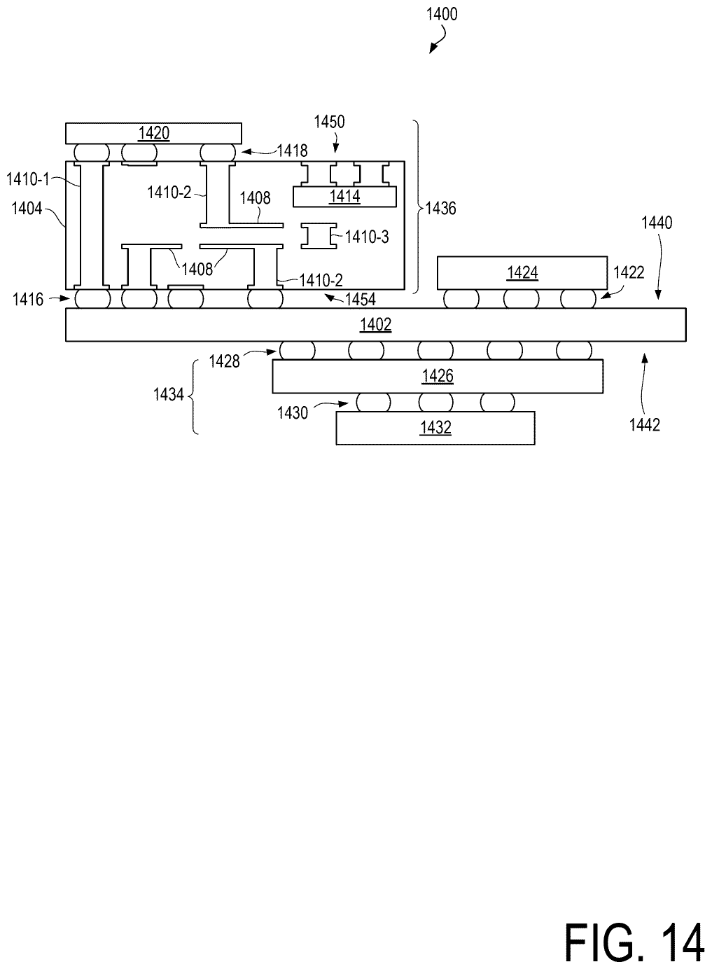

FIG. 14 is a cross-sectional side view of a microelectronic assembly 1400 that may include any of the embodiments disclosed herein. The microelectronic assembly 1400 includes multiple integrated circuit components disposed on a circuit board 1402 (which may be a motherboard, system board, mainboard, etc.). The microelectronic assembly 1400 may include components disposed on a first face 1440 of the circuit board 1402 and an opposing second face 1442 of the circuit board 1402; generally, components may be disposed on one or both faces 1440 and 1442.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The microelectronic assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpackaged integrated circuit component that includes one or more integrated circuit dies (e.g., the die 1202 of FIG. 12, the integrated circuit 1300 of FIG. 13) and/or one or more other suitable components.

The unpackaged integrated circuit component 1420 comprises solder bumps attached to contacts on the die. The solder bumps allow the die to be directly attached to the interposer 1404. In embodiments where the integrated circuit component 1420 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit die, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through-silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The integrated circuit assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the embodiments disclosed herein. For example, any suitable ones of the components of the electrical device 1500 may include one or more of the microelectronic assemblies 1400, integrated circuit components 1420, integrated circuits 1300, integrated circuit dies 1202, or structures disclosed herein. A number of components are illustrated in FIG. 15 as included in the electrical device 1500, but any one or more of these components may be omitted or duplicated, as suitable for the application. In some embodiments, some or all the components included in the electrical device 1500 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1500 can comprise one or more processor units 1502 that are heterogeneous or asymmetric to another processor unit 1502 in the electrical device 1500. There can be a variety of differences between the processor units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include another output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include another input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

Thus, embodiments of an improved via structure for use with the embedded component have been provided. The provided embodiments advantageously enable the use of finer pitch architectures and high-density input/output (I/O) designs in multi-chip packaging.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### Examples

Example 1 is an apparatus, comprising: mold structure comprising a face having a first portion with electrical contacts for an integrated circuit (IC) die and a photonic integrated circuit (PIC) die, and a second portion comprising optical interconnects; a substrate layer comprising one or more redistribution layers (RDLs) patterned on the electrical contacts on the first portion; a glass layer having an upper surface and a lower surface, the upper surface including a cavity, the cavity having therein a plurality of through-glass vias (TGVs) extending substantially perpendicularly to the lower surface; and
the mold structure attached to the glass layer such that the substrate layer is located in the cavity and the second portion of the mold structure is flush with the upper surface of the glass layer.

Example 2 includes the subject matter of Example 1, wherein the substrate layer comprises one or more vias, and the vias have walls that taper outward traveling axially away from the first portion.

Example 3 includes the subject matter of any one of Examples 1 or 2, wherein the one or more RDLs provide local electrical communication between the IC and the PIC.

Example 4 includes the subject matter of any one of Examples 1-3, further comprising a bond film located in between the cavity and the substrate layer.

Example 5 includes the subject matter of Example 3, wherein the bond film extends upward around a periphery of the substrate layer to a height greater than a thickness of the bond film; and further comprising an air gap adjacent to the bond film and between the PIC and the bond film.

Example 6 includes the subject matter of Example 5, further comprising an air gap located between the substrate layer and a wall of the cavity, above the bond film.

Example 7 includes the subject matter of any one of Examples 1-6, wherein the glass layer comprises silicon and oxygen.

Example 8 includes the subject matter of any one of Examples 1-6, wherein the glass layer comprises silicon, oxygen, and aluminum, boron, or an alkaline-earth metal.

Example 9 includes the subject matter of any one of Examples 1-8, wherein the glass layer has a thickness in a range of about 20 microns to about 2 millimeter.

Example 10 includes the subject matter of any one of Examples 1-9, wherein respective TGVs have a diameter of about 2 to about 150 microns.

Example 11 includes the subject matter of any one of Examples 1-10, further comprising a waveguide in the glass layer to provide optical communication through the glass layer.

Example 12 includes the subject matter of Example 11, further comprising an index matching film, a mirror, or a lens oriented in the glass layer to assist optical communication through the glass layer.

Example 13 includes the subject matter of any one of Examples 10-12, further comprising a fiber array unit (FAU) attached to the glass layer and in optical communication with the PIC via a terminus of the waveguide.

Example 14 includes the subject matter of any one of Examples 10-13, wherein the substrate layer comprises a first one or more RDLs, and further comprising a second one or more RDLs located on the lower surface of the glass layer.

Example 15 includes the subject matter of Example 14, further comprising an arrangement of solder bumps located on the second one or more RDLs located on the lower surface of the glass layer

Example 16 is a substrate package that includes the subject matter of any one of Examples 1-15

Example 17 includes the subject matter of Example 16, further comprising a printed circuit board (PCB) attached to the substrate package.

Example 18 is a method, comprising: fabricating a mold structure comprising a face having a first portion with electrical contacts for an integrated circuit (IC) die and a photonic integrated circuit (PIC) die, and a second portion comprising optical interconnects for the PIC; locating a thermal decomposable polymer layer on the second portion; locating a metal etch stop over the second portion; patterning one or more redistribution layers (RDLs) on the electrical contacts on the first portion; overlaying the one or more RDLs with a bond film; and removing the bond film and etch stop over the second portion.

Example 19 includes the subject matter of Example 18, further comprising: creating one or more vias in the one or more RDLs, the vias having walls that taper outward traveling axially away from the first portion.

Example 20 includes the subject matter of any one of Examples 18 or 19, further comprising,
creating a glass layer having an upper surface and a lower surface, the upper surface including a cavity, the cavity having therein a plurality of through-glass vias (TGVs) extending substantially perpendicularly to the lower surface; and attaching the mold structure to the glass layer such that the one or more RDLs are located in the cavity and the second portion of the mold structure is flush with the upper surface of the glass layer.

Example 21 includes the subject matter of any one of Examples 18-20, further comprising locating a bond film in between the cavity and the one or more RDLs.

Example 22 includes the subject matter of Example 21, further comprising causing the bond film to extend upward around a periphery of the one or more RDLs to a height greater than a thickness of the bond film.

Example 23 includes the subject matter of Example 22, further comprising creating an air gap between the one or more RDLs and a wall of the cavity, above the bond film.

Example 24 includes the subject matter of Example 21, further comprising: etching the bond film from TGV openings; and filling TGVs with conductive material to create electrically communicative pathways from TGVs to RDLs.

Example 25 includes the subject matter of any one of Examples 20-24, further comprising creating one or more optical waveguides in the glass layer to connect the PIC to at least one terminus in the glass layer.

Example 26 includes the subject matter of Example 25, further comprising patterning multiple RDL on the lower surface of the glass layer and attaching solder bumps to the lower surface of the glass layer.

What is claimed is:

1. An apparatus, comprising:
mold structure comprising a face having a first portion with electrical contacts for an integrated circuit (IC) die and a photonic integrated circuit (PIC) die, and a second portion comprising optical interconnects;
a substrate layer comprising one or more redistribution layers (RDLs) patterned on the electrical contacts on the first portion;
a glass layer having an upper surface and a lower surface, the upper surface including a cavity, the cavity having therein a plurality of through-glass vias (TGVs) extending substantially perpendicularly to the lower surface; and
the mold structure attached to the glass layer such that the substrate layer is located in the cavity and the second portion of the mold structure is flush with the upper surface of the glass layer.

2. The apparatus of claim 1, wherein the substrate layer comprises one or more vias, and the vias have walls that taper outward traveling axially away from the first portion.

3. The apparatus of claim 1, wherein the one or more RDLs provide local electrical communication between the IC and the PIC.

4. The apparatus of claim 1, further comprising a bond film located in between the cavity and the substrate layer.

5. The apparatus of claim 4, wherein the bond film extends upward around a periphery of the substrate layer to a height greater than a thickness of the bond film; and further comprising an air gap adjacent to the bond film and between the PIC and the bond film.

6. The apparatus of claim 5, further comprising an air gap located between the substrate layer and a wall of the cavity, above the bond film.

7. The apparatus of claim 1, further comprising a waveguide in the glass layer to provide optical communication through the glass layer.

8. The apparatus of claim 7, further comprising an index matching film, a mirror, or a lens oriented in the glass layer to increase optical communication through the glass layer.

9. The apparatus of claim 1, further comprising a fiber array unit (FAU) attached to the glass layer and in optical communication with the PIC via a terminus of a waveguide.

10. The apparatus of claim 1, wherein the substrate layer comprises a first one or more RDLs, and further comprising a second one or more RDLs located on the lower surface of the glass layer.

11. The apparatus of claim 10, further comprising an arrangement of solder bumps located on the second one or more RDLs located on the lower surface of the glass layer.

12. A substrate package comprising the apparatus of claim 11, and further comprising a printed circuit board (PCB).

13. A method, comprising:
fabricating a mold structure comprising a face having a first portion with electrical contacts for an integrated circuit (IC) die and a photonic integrated circuit (PIC) die, and a second portion comprising optical interconnects for the PIC;
locating a thermal decomposable polymer layer on the second portion;
locating a metal etch stop over the second portion;
patterning one or more redistribution layers (RDLs) on the electrical contacts on the first portion;
overlaying the one or more RDLs with a bond film; and
removing the bond film and etch stop over the second portion.

14. The method of claim 13, further comprising creating one or more vias in the one or more RDLs, the vias having walls that taper outward traveling axially away from the first portion.

15. The method of claim 13, further comprising,
creating a glass layer having an upper surface and a lower surface, the upper surface including a cavity, the cavity having therein a plurality of through-glass vias (TGVs) extending substantially perpendicularly to the lower surface; and
attaching the mold structure to the glass layer such that the one or more RDLs are located in the cavity and the second portion of the mold structure is flush with the upper surface of the glass layer.

16. The method of claim 15, further comprising locating a bond film in between the cavity and the one or more RDLs.

17. The method of claim 16, further comprising causing the bond film to extend upward around a periphery of the one or more RDLs to a height greater than a thickness of the bond film.

18. The method of claim 16, further comprising creating an air gap between the one or more RDLs and a wall of the cavity, above the bond film.

19. The method of claim 16, further comprising:
etching the bond film from TGV openings; and
filling TGVs with conductive material to create electrically communicative pathways from TGVs to RDLs.

20. The method of claim 19, further comprising creating one or more optical waveguides in the glass layer to connect the PIC to at least one terminus in the glass layer.
